(19) United States
(12) Patent Application Publication
(10) Pub. No.: US 2015/0056730 A1
(43) Pub. Date: Feb. 26, 2015

(54) SEMICONDUCTOR DEVICE AND METHOD FOR MANUFACTURING THE SAME

(71) Applicant: Verticle, Inc., Seoul (KR)

(72) Inventors: Kyu Sung Hwang, Cheonan (KR); Se Jong Oh, Anseong (KR); Myung Cheol Yoo, Seoul (KR); Moo Keun Park, Yongin (KR); Sang Don Lee, Pyeongtaek (KR)

(73) Assignee: VERTICLE, INC.

(21) Appl. No.: 14/528,873

(22) Filed: Oct. 30, 2014

Related U.S. Application Data
(63) Continuation of application No. PCT/KR2012/003341, filed on Apr. 30, 2012.

(30) Foreign Application Priority Data
Apr. 30, 2012 (KR) 10-2012-0045141

(51) Int. Cl. H01L 33/44; H01L 33/64; H01L 33/62

(52) U.S. Cl. CPC H01L 33/44; H01L 33/62; H01L 33/647; H01L 2933/0025; H01L 2933/0033; H01L 2933/0075; H01L 2933/0066
USPC 438/33

(57) ABSTRACT

The present invention relates to a semiconductor device, a manufacturing method thereof. More specifically, this invention is related to a chemical etching method in semiconductor device separation process without using dicing or scribing.

According to an example of the invention, a method for manufacturing a semiconductor device, the method comprising: forming a light emitting semiconductor device layer that emits light by current injection; and forming at least one metal layer with etch barrier plated thereon on the semiconductor device layer, wherein the at least one metal layer provides mechanical support to the semiconductor device, wherein the etch barrier is plated on the at least one metal layer in a direction that the etch barrier can prevent side wall under-cut when the street lines are separated by wet chemical etching.

### CROSS-REFERENCE TO RELATED APPLICATION

This application is a continuation of PCT/KR2012/003341 filed on Apr. 30, 2012, which claims priority to Korean Application No. 10-2012-0045141 filed Apr. 30, 2012, which applications are incorporated herein by reference.

### TECHNICAL FIELD

The present invention relates to a semiconductor device, a manufacturing method thereof. More specifically, this invention is related to a chemical etching method in semiconductor device separation process without using dicing or scribing.

### BACKGROUND ART

Conventional semiconductor device separation methods are including mechanical and chemical processes after forming plural semiconductor devices on the wafer. FIG. 1 shows wafer structure and street line to separate individual semiconductor device from the wafer. FIG. 1 shows a cross sectional view of semiconductor and example of the street line. FIG. 1 also shows the street line on the wafer top view. Referring to FIG. 1, conventional wafer (100) consists of three layers. The first layer (110) is a semiconductor device layer containing materials, such as Si and GaN. The third layer (130) is formed by plating method that has partial function of the second layer (120). The fourth layer (140) also formed by plating that has function of heat dissipation, electrical conduction, and mechanical support. Dicing or scribing is typical chip separation method for separating individual device from the wafer (100). Dicing usually utilizes diamond saw, diamond scriber or laser scriber, in which those processes are using very expensive equipment and long process time. Conventional technologies have disadvantages due to lower process yield, lower equipment performance, and high process cost.

At first, considering the process yield issue, mechanical chip separation methods that include conventional dicing, scribing, and laser scribing, individual semiconductor device can be separated along the grid line or street line as shown in FIG. 2. Therefore, it is slow process because each device is separated one at a time along the street line. Process yield becomes more important in case of hard substrate materials, such as GaN on sapphire and GaN on SiC. In addition, separation yield is greatly influenced by cracks or defects created during substrate grinding and polishing. When cutting line passes through the defective area, the chip separation yield is very low. Therefore, chip separation is known to be one of the most tedious and lowest yield process in the semiconductor production processes. In actual production, back-end as low as 50% process yield, while front-end is typically in the range of 90% in the GaN semiconductor manufacturing.

Next, considering the device performance, the chip performance can be degraded after separation in case of dicing and scribing by physical damage. For example, LED chip side wall where light emits can be damaged during the separation process, which is main cause of optical power loss.

In case of laser scribing, chip separation can be achieved by melting substrate material by laser beam. As a result, melted substrate materials can be accumulated on the chip side wall, which is another source of optical power loss of LED device.

Finally, considering the processing cost issue, chip separation process time for the typical GaN/sapphire wafers having 10,00˜12,000 chips per wafer is somewhere between 40 minute to 1 hour in case of conventional chip separation methods. This means only 24 to 36 wafers can be processed per machine (700 to 1,000 wafers per month), based on 24 hour per day operation. Therefore, in order to process mass production volume, multiple chip separation machines are required; meaning huge amount of capital investment is needed. In addition, consumable parts, such as diamond cutting wheel, diamond tips are very expensive. Moreover, major consumable part in laser scribing machine is laser source which is one of the most expensive items because the laser source frequently needs to be recharged to maintain constant laser beam energy.

The problems caused by conventional mechanical chip separation can be partially resolved by using chemical wet etching method. However, main issue of the chemical wet etching is side wall under-cut. As can be seen in FIG. 1, if the thickness of first layer (110) is less than few □micrometer, side wall under-cut is not a serious problem. However, in case of relatively thicker third layer (130) or fourth layer (140) than first layer (110), under-cut might be a serious problem when semiconductor devices are separated with wet chemical etching. Therefore, a new way to resolve the side wall under-cut is required in the wet chemical etching process.

Prior art for semiconductor device manufacturing and separation method is described in Korean published patent number 2007-0085374.

According to the Prior art of chemical chip separation processes does not take into consideration of the side wall under-cut issues. Hence, side wall under-cut could be a major issue in conventional chip separation processes. In addition, conventional chip separation method uses photo-resist in order to make easy chip separation. However, chip separation process might be difficult due to additional processing steps are required, such as planarization of photo-resist when the wafer is attached to wafer carrier because controlling photo-resist thickness is very difficult without removing the photo-resist.

The above information disclosed in this Background section is only for enhancement of understanding of the background of the invention and therefore it may contain information that does not form the prior art that is already known in this country to a person of ordinary skill in the art.

### SUMMARY OF THE DISCLOSURE

Accordingly, Accordingly, the present invention has been made in order to solve the above-described problems occurring in the prior art, and an object of the present invention is to provide a method for manufacturing a semiconductor device in semiconductor device separation and a semiconductor device manufactured by the method. More specifically, the objective of this invention is to provide a method to separate semiconductor devices using wet chemical etching and a semiconductor device manufactured by the method. In addition, objective of this invention is to provide a noble method to prevent the side wall under-cut by plated etch barrier layer in case wet chemical etching chip separation method is used.

In order to achieve above mentioned objective, this invention describes semiconductor fabrication process steps that include forming a light emitting semiconductor device layer by current injection, and forming a mechanical support with metal layers on above-mentioned semiconductor device layer. Further, in order to avoid the side wall under-cut during chip separation by wet chemical etching, etch barrier is formed by plating along the street lines.

Above mentioned semiconductor fabrication method includes; vacuum deposition of thin film metal layers consisting of reflector, CBL (Current Blocking Layer), etch Barrier, diffusion barrier, adhesion layer, and electrical transfer or spreading layers (here after thin metal layers) before forming one or multiple layers.

Depending on example of the invention, forming steps of above-mentioned metal layers are including; 1) plating the first metal layer and the first etch barrier on the semiconductor devices along the first pattern, and 2) plating the second metal layer and the second etch barrier on the first metal layer along the second pattern in order to prevent the side wall under-cut during the wet chemical etch separation.

Depending on example of the invention, forming steps of above-mentioned metal layers are including; 1) forming the first and second patterns consecutively on the first and second metal layers; 2) plating the etch barriers or etch stop layers on the first and second metal layers at the same time, in order to prevent device side wall under-cut when the above mentioned street lines are separated with wet chemical etching; 3) street lines and the first and second metal layers are filled with third metal plating at the same time.

Depending on example of the invention, forming steps of above-mentioned metal layers are including; 1) forming the first and second patterns consecutively on the first and second metal layers; 2) plating the etch stop layers on the first and second metal layers at the same time, in order to prevent device side wall under-cut when the above mentioned street lines are separated with wet chemical etching; 3) partial plating can be employed by protecting side wall and surface of the second metal layer using the third pattern when the street lines are filled with third metal plating.

Depending on example of the invention, forming steps of above-mentioned first metal layer on the semiconductor device are including; 1) total thickness of above-mentioned first metal layer and above-mentioned second metal can be more than 80 um. 2) If the plated metal hardness is in the range of 100-200 Hv, the first metal layer having more than 40 um thickness can be used.

Depending on example of the invention, forming steps of above-mentioned first metal layer on the semiconductor device are including; 1) forming the first photo-resist on the along the above-mentioned street lines of above-mentioned semiconductor devices step, 2) plating the first metal layer on the area where above-mentioned first photo-resist is not formed along the above-mentioned first pattern, and 3) plating the first etch barrier layer on the first metal layer.

Above mentioned first metal can be selected from Cu or Cu alloy, and combination of Cu and Cu alloy. Also, other similar single or multiple plated metal layers can be inserted for thermal stress relief.

Depending on example of the invention, forming process steps of above-mentioned second metal layer are including; 1) forming a second photo-resist on the inverse pattern of the above-mentioned second pattern; 2) plating second metal layer on the area where the second photo-resist is not formed along the above-mentioned second pattern; 3) removing the second photo-resist; 4) forming the third photo-resist on the second metal layer along the above-mentioned street lines; 5) plating above-mentioned second etch stop layer on the second metal layer where the third photo-resist is not formed; 6) removing above-mentioned third photo-resist.

Depending on example of the invention, forming process steps of above-mentioned second metal layer are including; 1) forming the second photo-resist on the inverse pattern of the above-mentioned second pattern; 2) plating the second metal layer on the area where the second photo-resist is not formed along the second pattern; 3) removing the above-mentioned second photo-resist; 4) plating etch stop layers on the entire surface of the above-mentioned first and second metal layers; 5) plating third or same metals used for the first and second metal layers on the street lines and the first and second metal layers concurrently.

Depending on example of the invention, forming steps of above-mentioned second metal layer are including; 1) forming the second photo-resist on the mirror image of the second pattern; 2) plating the second metal layer on the area where the second photo-resist is not formed along the second pattern; 3) removing the above-mentioned second photo-resist; 4) plating the etch barrier layer on the entire surface of the first and second metal layers; 5) partial plating can be employed by protecting side wall and surface of the above-mentioned second metal layer using the third pattern. The street lines are filled with third metal plating or same metal plating used in the first and second metal layer.

Above mentioned second metal can be selected from Cu or Cu alloy, and combination of Cu and Cu alloy. Also, other similar single or multiple plated metal layers can be can be inserted for thermal stress relief.

Above mentioned third metal can be used as the same first metal.

Fabrication process steps of above-mentioned semiconductor device are including; 1) first chip separation step: separating the street lines of the above-mentioned semiconductor device by mechanical or wet chemical etching; 2) second chip separation step: metal layer formed on the street lines of the above-mentioned semiconductor device where the etch barrier is not plated, is separated by wet chemical etching; 3) forming a support layer that hold the chips on the wafer after above-mentioned first chip separation step and before the above mentioned second chip separation step.

Fabrication process steps of above-mentioned support layer are including; 1) forming a photo-resist including positive photo-resist on the above-mentioned semiconductor device; 2) attaching UV tape on the above mentioned positive photo-resist.

Coating steps of above-mentioned photo-resist including positive photo-resist are; 1) photo-resist thickness can be made more than 3 um from the device surface; 2) the protecting PR should be coated enough to fill the spacing between individually separated devices.

Above-mentioned semiconductor fabrication method includes; 1) after completion of the above-mentioned second chip separation step, an expanding tape having higher adhesion strength than the adhesion strength between the positive PR and the UV tape attaches to the second metal layer; 2) transferring separated chips from support layer to expanding tape; 3) removing the support layer and cleaning.

This invention relates to the method of fabricating semiconductor device and separating the semiconductor devices by wet chemical etching. By employing the etch barrier layer in the metal layers, this invention provides a noble way to prevent the side wall under-cut during the chip separation by wet chemical etching.

Because this invention is using a wet chemical etching technology for semiconductor device separation, it has following advantages over to the mechanical chip separation technologies; 1) higher process yield, 2) lower device performance degradation, and 3) relatively lower cost.

### BRIEF DESCRIPTION OF THE DRAWINGS

The above and other objects, features and advantages of the present invention will be more clearly understood from the following detailed description taken in conjunction with the accompanying drawings, in which:

FIG. 1 shows wafer structure and street lines for the semiconductor device separation.

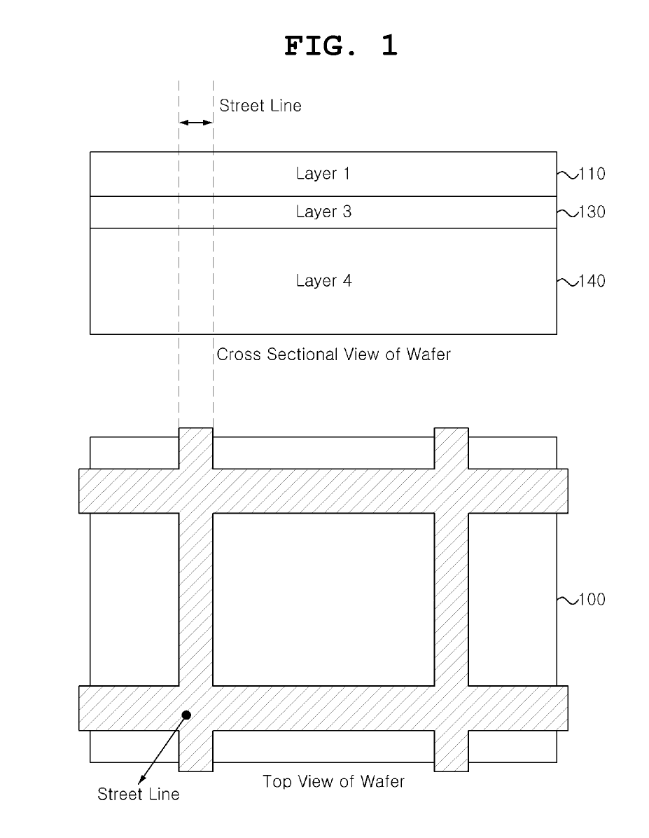

FIG. 2 shows a cross sectional view of plural devices formed on the wafer according to the processing example of this invention.

FIG. 3 shows an entire process flow according to the processing example of this invention.

FIG. 4 shows a process flow of the first metal layer formed on the wafer according to the processing example of this invention.

FIG. 5 shows a process flow of the second metal layer formed on the wafer according to the processing example of this invention.

FIG. 6 shows a process flow of the support layer formed on the wafer according to the processing example of this invention.

FIG. 7 shows a cross sectional view of the first photo-resist formed on the wafer according to the processing example of this invention.

FIG. 8 shows a cross sectional view of the first metal layer plated on the wafer according to the processing example of this invention.

FIG. 9 shows a cross sectional view of the wafer where the first photo-resist is removed according to the processing example of this invention.

FIG. 10 shows a cross sectional view of the wafer where the first etch stop layer is plated on the first metal layer according to the processing example of this invention.

FIG. 11 shows a cross sectional view of the second photo-resist formed on the wafer according to the processing example of this invention.

FIG. 12 shows a top view of the second photo-resist formed on the wafer according to the processing example of this invention.

FIG. 13 shows a cross sectional view of the second metal layer plated on the wafer according to the processing example of this invention.

FIG. 14 shows a cross sectional view of the wafer where the second photo-resist is removed according to the processing example of this invention.

FIG. 15 shows a cross sectional view of the wafer where the third photo-resist formed on the second metal layer along the street lines according to the processing example of this invention.

FIG. 16 shows a cross sectional view of the wafer where the third photo-resist formed on the second metal layer along the street lines according to the processing example of this invention.

FIG. 17 shows a cross sectional view of the wafer where the third photo-resist is removed according to the processing example of this invention.

FIG. 18 shows a cross sectional view of the wafer where the street lines of the first and the second layers are separated according to the processing example of this invention.

FIG. 19 shows a cross sectional view of the wafer where the support layer is formed according to the processing example of this invention.

FIG. 20 shows a cross sectional view of the wafer where the metal is etched without having protected by etch stop layer according to the processing example of this invention.

FIG. 21 shows a cross sectional view of the wafer where the expanding tape is attached on the second metal layer according to the processing example of this invention.

FIG. 22 shows a cross sectional view of the wafer where the support layer is removed according to the processing example of this invention.

FIG. 23 shows a cross sectional view of the wafer where the etch stop layer and multiple metal layers are plated according to another processing example of this invention.

FIG. 24 shows a cross sectional view of the wafer where the etch stop layer and multiple metal layers are plated according to another processing example of this invention.

### DETAILED DESCRIPTION OF THE DISCLOSURE

Hereinafter, embodiments of the present invention will be described in detail with reference to the accompanying drawings. It should be noted that the same reference symbols are assigned to the same components as much as possible even when the components are illustrated in different drawings. The scope of the present invention is not limited or restricted to these embodiments. In the following description, detailed descriptions of related well-known components or functions that may unnecessarily make the gist of the present invention obscure will be omitted.

Each region in the drawings may be simplified or somewhat exaggerated to clearly show the features of the present invention, and the dimensions of each region in the drawings may not be exactly identical to the actual dimensions of the products of the present invention.

Any person skilled in the art may easily modify the dimensions (e.g., length, circumstance, thickness, etc.) of each element in the drawings and apply these modifications to actual products, and these modifications will fall within the scope of the present invention.

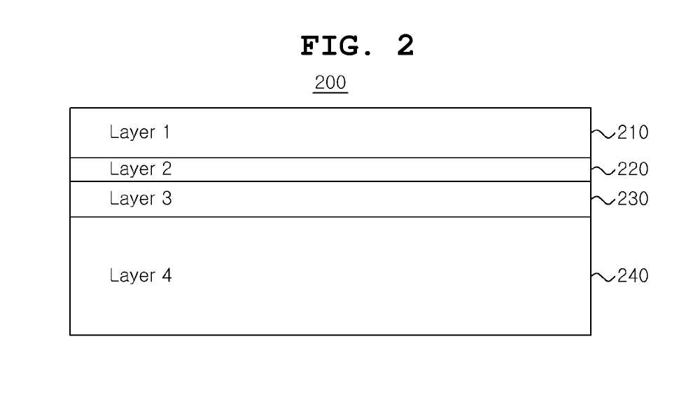

In the following, detailed semiconductor manufacturing methods are described from FIG. 2 to FIG. 22 according to the processing example of this invention.

FIG. 2 shows a cross sectional view of plural devices formed on the wafer according to the processing example of this invention. As shown in the FIG. 2, the wafer (200) consists of four different layers.

The first layer (210) is semiconductor device layer containing, such as Si, GaN. Hereafter, the first layer (210) is called either first layer or semiconductor device layer. In case the first layer is GaN based light emitting layer, it contains n-GaN and p-GaN, multiple quantum well active layer (MQW) in between n-GaN and p-GaN. Light is emitting when current is injected between n-GaN and P-GaN by electron and hole recombination process.

The second layer (220) is placed in between semiconductor device layer (210) and metal plated layer (230), which is consisted with multiple functional metal layers including reflector, CBL (Current Block Layer), etch barrier, diffusion barrier, adhesion, and electrical transfer or spreading layers. The second layer (220) may contains one or multiple combination of metals that include Pt (platinum), Au (Gold), Ag (silver), Cr (chromium), Ti (titanium), Mo (molybdenum), W (tungsten), Ni (nickel). The second layer (220) can also contain vacuum deposited inorganic materials, such as Si, SiO2. Hereafter, the second layer (220) is called either second layer or diffusion barrier layer.

The third layer (230) is formed by plating that has partial functioning of the second layer. Hereafter, the third layer (230) is called either third layer or metal layer.

The fourth layer (240) is formed by plating and has multiple functions that include heat dissipation, electrical conduction, and mechanical support. Hereafter, the fourth layer (240) is called either fourth layer or second metal layer.

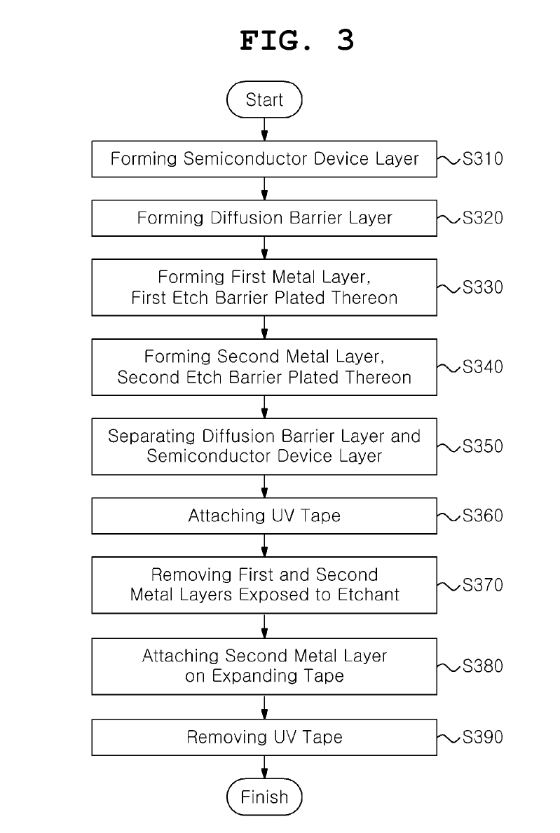

FIG. 3 shows an entire process flow according to the processing example of this invention. Referring to FIG. 3, semiconductor device is fabricated with forming a light emitting layer (S310) and diffusion barrier layer (S320) formed on the semiconductor device layer to prevent metal diffusion into the semiconductor device layer. In order to separate semiconductor devices, On top of diffusion barrier layer, the first etch barrier layer (S330) is plated along the street lines to prevent side wall under-cut during the chemical chip separation.

In this case, the first pattern is defined as entire area excluding street lines. In case of electroplating is used to form etch barrier, it is beneficial to cover the photo-resist few mm inward from the wafer edge to provide electrical contacts. In case the first metal layer and second metal layer are plated with pure Cu, not with Cu alloy, and the total plating thickness is more than 80 um, it is desirable to form the first metal layer thickness more than 40 um. The reason is that since the area of the second metal layer is plated smaller than that of the first metal layer, therefore, fringe area of the semiconductor device is mostly supported by the first metal layer. If the first layer thickness is too thin, cracks might be generated around the device fringe due to plating stress and chip handling, therefore, it is desirable to maintain the first metal layer thickness more than 40 um.

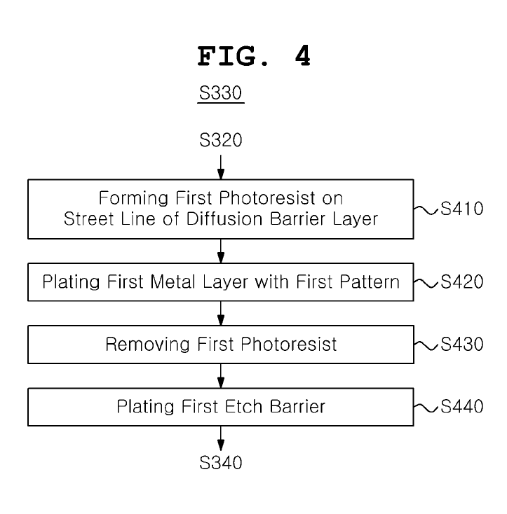

In the following, detailed process flow of forming a first metal (S330) layer is described as references to the FIG. 4 and figures from 4 through 7. FIG. 4 shows a process flow of the first metal layer formed on the wafer according to the processing example of this invention.

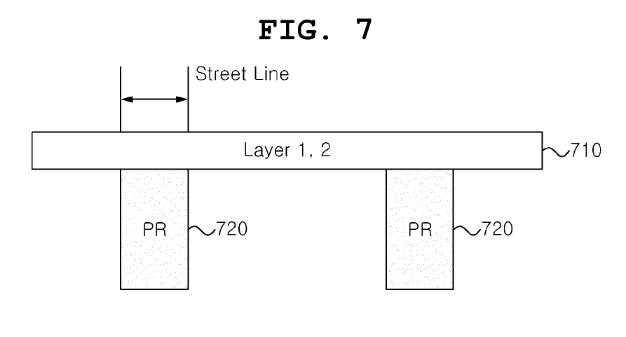

As shown in the FIG. 4, a method of forming the first metal layer (S330) is first, forming first photo-resist (720) along the street lines of the first and second layers (710); (S410). At this stage, the first photo-resist (720) prevents the first metal layer from plating the street lines. FIG. 7 shows a cross sectional view of the first photo-resist formed on the wafer according to the processing example of this invention.

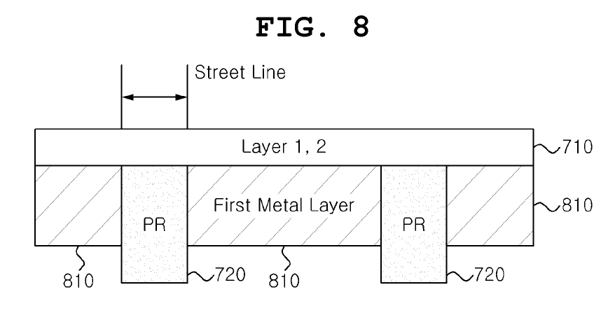

As shown in FIG. 8, the method of forming the first metal layer (S330) is to plate first metal (810) on the area where the first photo-resist (720) is not formed; (S420). The first metal (810) consists of Cu or Cu alloys. In case of pure Cu, it is beneficial to maintain the Vickers' hardness of the first metal layer (810) lower than 120 Hv. FIG. 8 shows a cross sectional view of the first metal layer plated on the wafer.

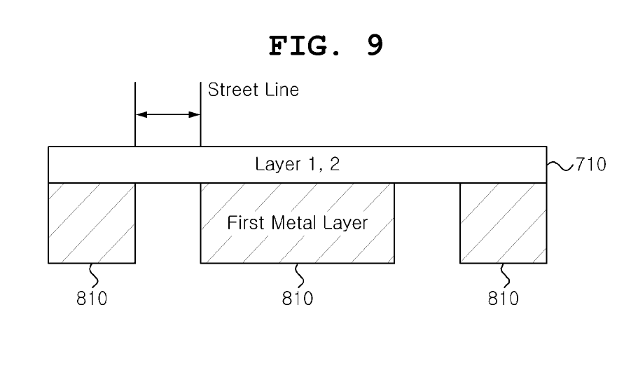

As shown in FIG. 9, a method of forming the first metal layer (S330) is to remove photo-resist (720); (S430). FIG. 9 shows a cross sectional view of the wafer where the first photo-resist is removed according to the processing example of this invention.

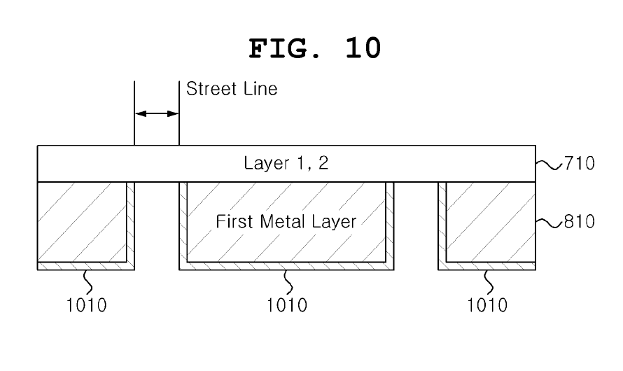

As shown in FIG. 10, a method of forming the first metal layer (S330) is to plate the first etch barrier layer (1010) with metals inert to the etchant on the first metal layer (810) in order to prevent side wall under-cut in case when wet chemical etching method is used for the chip separation; (S440). FIG. 10 shows a cross sectional view of the wafer where the first etch stop layer is plated on the first metal layer according to the processing example of this invention.

Returning back to the FIG. 3, in order to prevent the side wall under-cut during the separating with wet chemical etching of street lines, the second metal layer plated with etch barrier forms on the first metal layer along the second pattern, (S340).

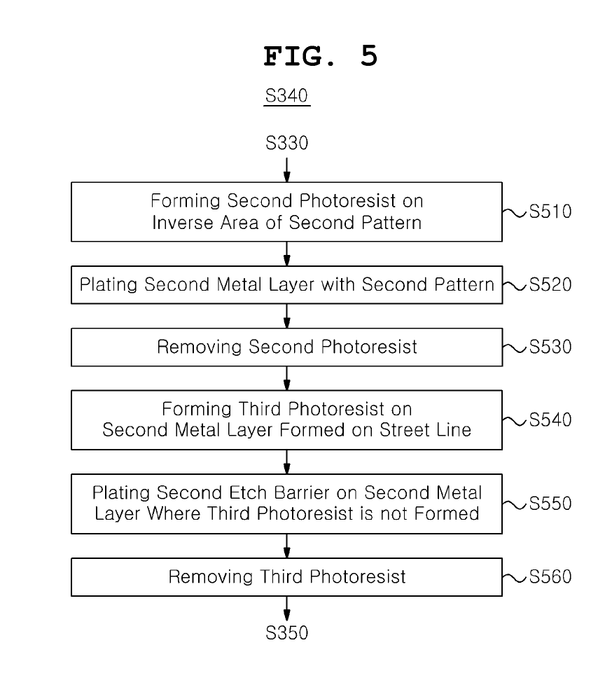

Next, details of forming the second metal layer (S340) are described as references to the FIGS. 5, 11, and 17.

FIG. 5 shows a process flow of the second metal layer formed on the wafer according to the processing example of this invention.

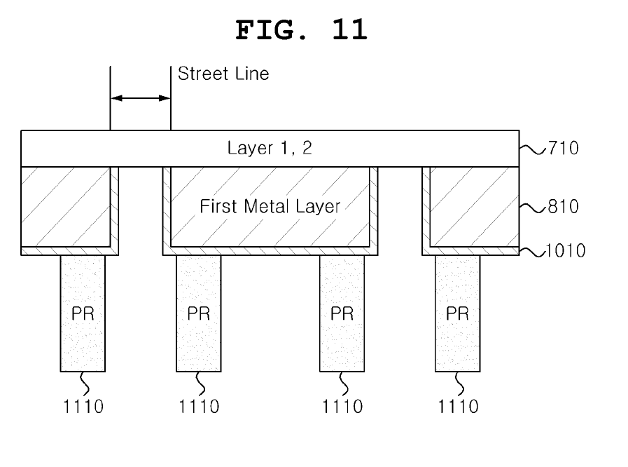

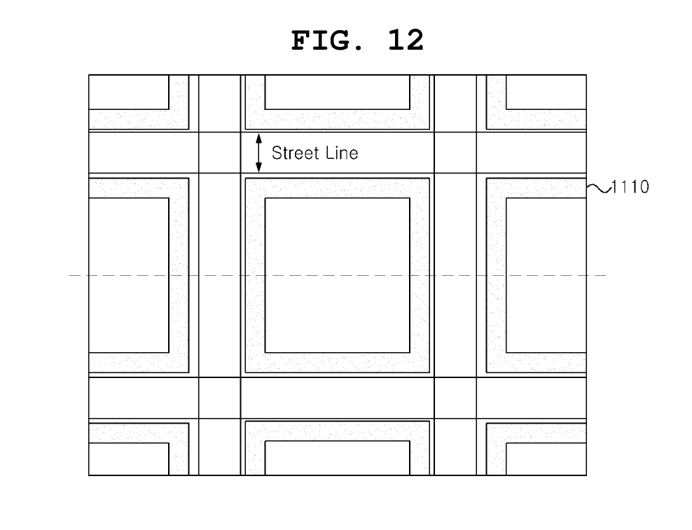

According to the FIG. 5, a method of forming the second metal layer (S340) is to form the second photo-resist (1110) on the mirror image of the second pattern as shown in FIG. 11; (S510). At this stage, the photo-resist (110) is formed on the pre-determined area around border of the street lines of the inverse pattern. When the wet chemical etching is used for chip separation, it acts as non-etched area by chemical etchant. It can be formed as top view of the FIG. 12.

As explained in FIG. 2 and FIG. 10, the etch barrier layer materials can be selected depending on the etch selectivity of the first and second metal layers and chemical etchants. For example, the chemical etchants comprising of CuCl2, and CuFe3 or the mixture of two chemicals can be used in case of the first and second metal layers are Cu or Cu alloy. Also, nitric acid base etchant can be used.

Pure Au or NiAu, Pt, Pd can be used for the etch barrier. In case pure Au etch barrier, it is beneficial to make Au thickness in between 0.5 micrometer and 1.5 micrometer. In order to secure etch protection, it is necessary to maintain Au thickness more than 0.5 micrometer. Further, in order to secure the bonding between the first and second metal layers, it is beneficial to make Au thickness more than 1.5 micrometer.

In case of NiAu etch barrier, Ni 0.5 micrometer, Au 1.0 micrometer is desirable thickness, and Ni should be less than 0.5 micrometer. The reason for selecting optimal etch barrier thickness is the same as explained previously.

In case of Au—Sn Eutetic alloy etch barrier, part or entire layer of Pure Ni/AuSn or Ni/Au/AuSn can be used. The thicknesses of 0.5 micrometer Ni, 1 micrometer Au, 3-5 micrometer Au—Sn are desirable for etch barrier.

Even though it is not fully explained in the FIG. 2 or FIG. 10, the single or multiple third metal layers can be inserted between semiconductor device layer and single or multiple metal layers for stress relief purpose. The stress relief layer plays an important role to prevent creating the cracks caused by thermal shock between thermal coefficient difference of metal layer and semiconductor layer. The cracks are known to be main source of device performance degradation and poor reliability. The third metal can be comprised with at least at least one or multiple combination of metals. The third metal should be lower thermal expansion coefficient than Cu, but higher than GaN in order to relieve the internal stress and thermal expansion coefficient. In case the first and second metal layers have tensile stress property, it is desirable to select the third metal layers with compressive stress property. Metals including Ni, Cr, NiCo alloy or Mo, W can be used as third metal plated layers. At least one layer of Cr can be inserted in the Ni/Cr/Ni or Ni/Cr/NiCr/Ni plating, however, to increase the adhesion, Ni can be inserted before or after Cr plating. In this case, Ni thickness needs to be more than 0.2 □micrometer per layer and Cr thickness needs to be more than 1 micrometer based on the cumulative plating thickness.

Another example is to insert Ni—Co alloy as a stress relief layer (third metal layer). Maintaining Co content and current density is one of the important factors to make zero stress of alloy plating layer.

In addition, the first and second metal layers are comprised with Cu or other metals having the stress level within +/−10% of pure Cu and the total thickness more than 80 um, the first metal layer thickness more than 40 um is desirable.

The first metal layers comprising either Cu or Cu alloy having the plating stress within 0.2 kgf/mm²˜+1.0, kgf/mm² are desirable.

The second metal layers comprising with Cu or Cu alloy having the plating stress in the range −0.2 kgf/mm²˜+1.0 kgf/mm², the first metal layer thickness needs to be 55%˜65% of total plating thickness, and the second metal layer having the plating stress in the range of −1.0 kgf/mm²˜+1.0 kgf/mm2 with remaining 35˜45% thickness.

FIG. 11 shows a cross sectional view of the second photo-resist formed on the wafer and the FIG. 12 shows a top view of the second photo-resist formed on the wafer. Dotted line in FIG. 12 depicts cross sectional line shown in FIG. 11.

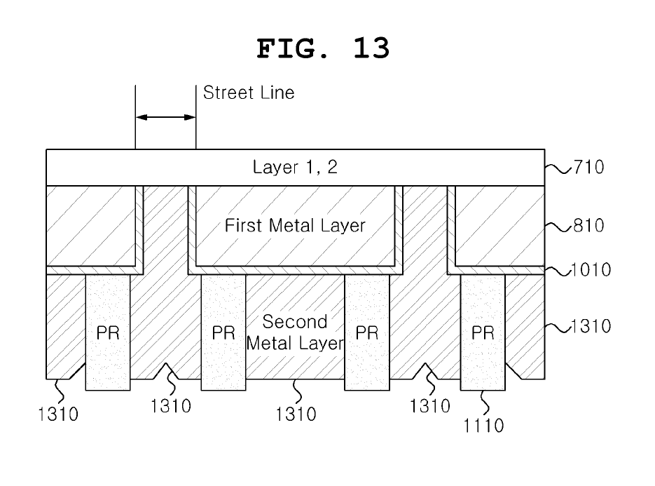

As shown in FIG. 13, a method forming the second metal layer (S340) is to plate second metal (1310) along the second pattern where the second photo-resist is not formed on the wafer; (S520). The second metal layer is comprised with Cu or Cu alloys. In case of pure Cu, more than 120 Hv Vickers' hardness is desirable. FIG. 13 shows a cross sectional view of the second metal layer plated on the wafer according to the processing example of this invention.

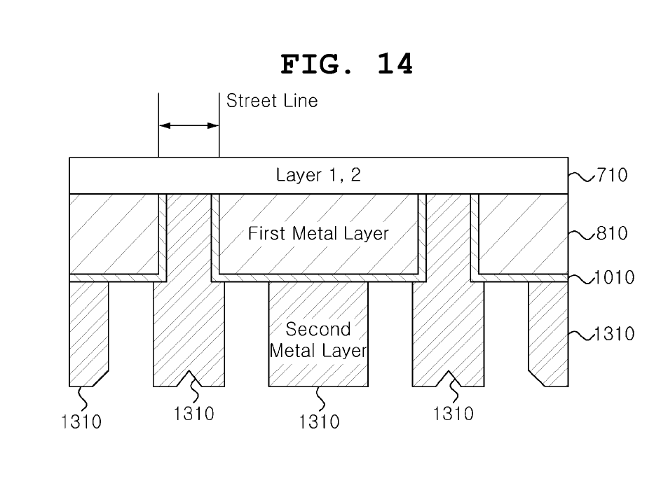

As shown in FIG. 12, a method forming the second metal layer (S340) is to remove the second photo-resist (1110); (S530). FIG. 14 shows a cross sectional view of the wafer where the second photo-resist is removed according to the processing example of this invention.

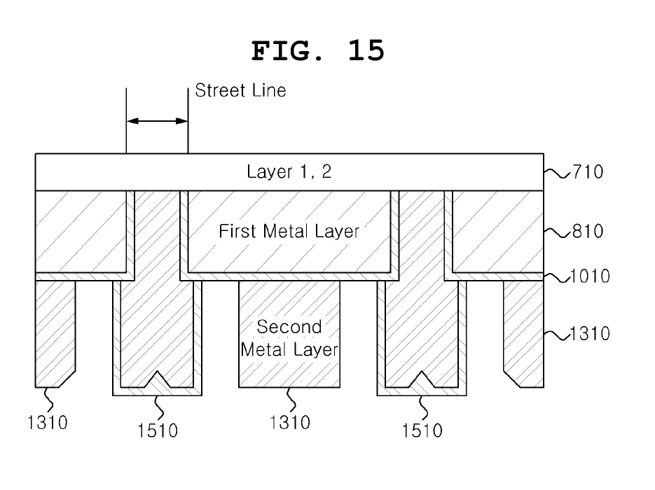

As shown in FIG. 15, a method forming the second metal layer (S340) is to form the third photo-resist (1510) on the second metal along the street lines; (S540). In this case, the third photo-resist prevents plating of the second etch barrier when semiconductor device is separated by wet chemical etching method. FIG. 15 shows a cross sectional view of the wafer where the third photo-resist formed on the second metal layer along the street lines according to the processing example of this invention.

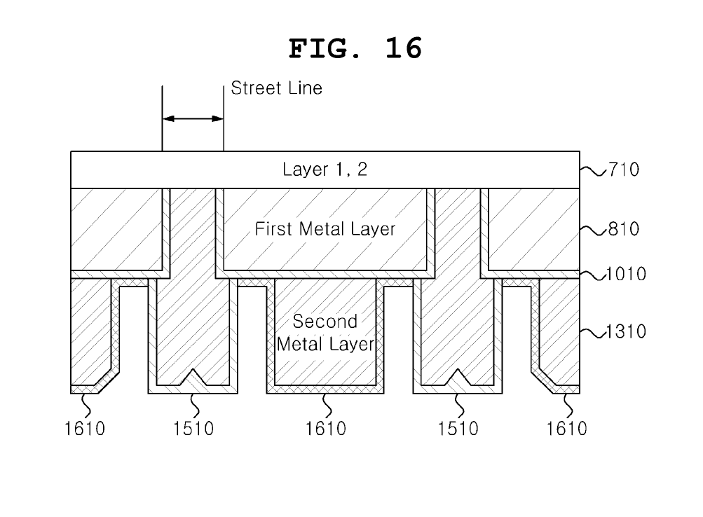

As shown in FIG. 16, a method of forming the second metal layer (S340) is to plate the second etch barrier layer (1610) on the second metal layer where the third photo-resist (1510) is not formed; (S550). FIG. 16 shows a cross sectional view of the wafer where the third photo-resist formed on the second metal layer along the street lines according to the processing example of this invention.

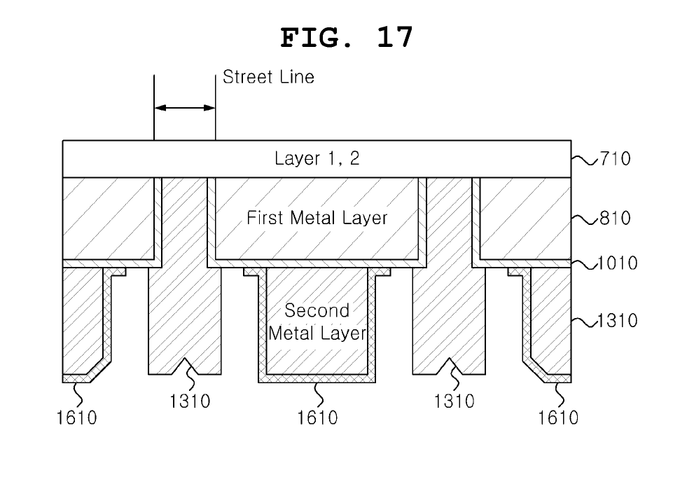

As shown in FIG. 17, a method of forming the second metal layer (S340) is to remove the third photo-resist (1510); (S560). FIG. 17 shows a cross sectional view of the wafer where the third photo-resist is removed according to the processing example of this invention.

The purpose of separately describing the first photo-resist (720), the second photo-resist, and the third photo-resist (1610) is based on semiconductor fabrication process order. The first photo-resist (720), the second photo-resist, and the third photo-resist (1610) can be an identical material or one of them can be chosen from different material.

In addition, the first etch barrier (1010) and the second etch barrier (1610) are also described separately based on the semiconductor fabrication process order. The first etch barrier (1010) and the second etch barrier (1610) can be an identical material or one of them can be chosen from different material.

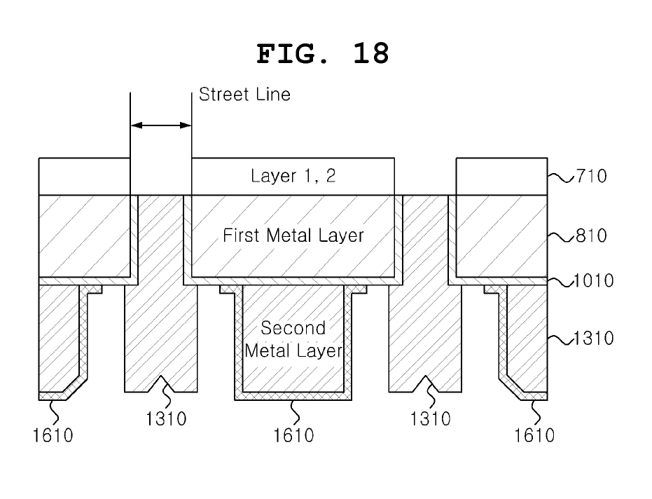

Returning back to FIG. 3, as shown in FIG. 18, a fabrication method of semiconductor device is the street lines of the first and second layer (710) are separated by mechanical or wet chemical etching (S350). FIG. 18 shows a cross sectional view of the wafer where the street lines of the first and the second layers are separated according to the processing example of this invention. A fabrication method of semiconductor device is to form support layer in order to attach the chips on the wafer. By doing this, chips can be protected and securely attached to the wafer during the fabrication process (S350).

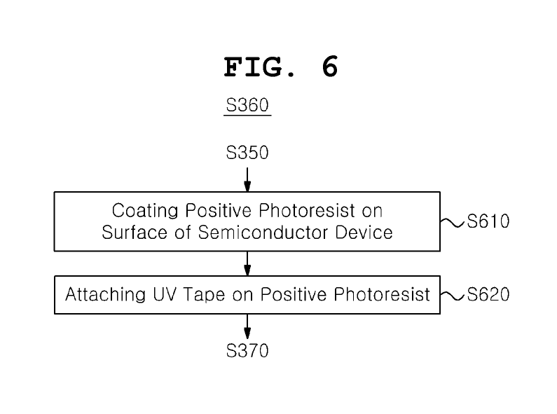

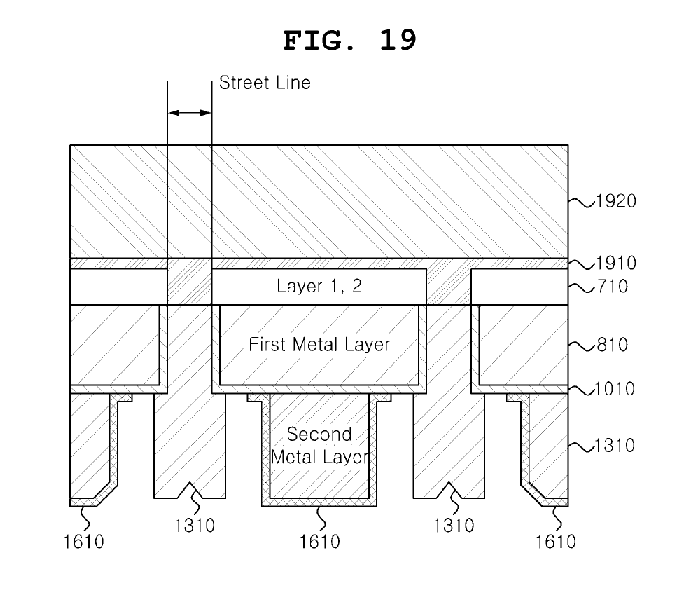

In the following, a method of forming support layer (S360) is described as reference to the drawings in FIG. 6 and FIG. 19.

FIG. 6 shows a process flow of the support layer formed on the wafer according to the processing example of this invention.

FIG. 19 shows a cross sectional view of the wafer where the support layer is formed according to the processing example of this invention.

Refer to the FIGS. 6 and 19, a method forming the support layer (S360) is to coat positive PR (1910) on the semiconductor device surface (S610). In this case forming method of the support layer (S360) is to form PR thickness higher than device height in order to protect the side wall and surface of the layer 1 and 2 (710) from the etchant when the semiconductor devices are separated by wet chemical etching. Considering the commercial device thickness, more than 3 □m PR thickness is desirable.

In case of using UV tape or non-photo sensitive adhesive tape without PR coating on the support layer, device side wall is not properly covered with adhesive, therefore, side wall and surface of layer 1 and 2 (710) can be attacked by chemical or mechanically damaged during the chip separation. Positive PR is coated on the wafer surface and cured without exposure. It can be removed by developer after UV exposure.

A method of forming support layer (S360) is to attach UV tape (1920) on the positive PR (1910) that loosens adhesiveness after exposing with UV (S620).

The reason for using the UV tape is to make easy removal of separated chips when they are transferred to the expanding tape. When UV tape is exposed to UV, it loses the adhesiveness and can be easily removed with positive PR.

As shown in FIG. 6, even though the support layer is formed with positive PR (1910) and UV tape (1920), it also can be formed by other materials that can protect the chips from the chemicals during the chip separation by wet chemical etching. It is beneficial to choose support material that can be easily removed after fabrication processing. If too strong adhesive materials are used, chip surface can be damaged or chip cannot be removed during chip transfer.

However, in the case of UV tape on the PR is used as a support layer, the PR should be positive type because it can be stripped by UV exposure. Negative PR cannot be used because it can be cured and hardened after UV exposure.

Photo-resist can also affect in choosing etchant to etch the street lines of the first and second metal layers. Since the metal layer plated on the street line can be formed with the second metal layer at the same time, it can be Cu or Cu alloy or third metal layer containing Cu alloy. The chemical etchant for these metals should be selected from the one that should not attack the Photo-resist after metal etching; i.e. the chemical etchant containing alkali additives attacks most of PR, hence etchant should be selected excluding the above alkali containing etchant.

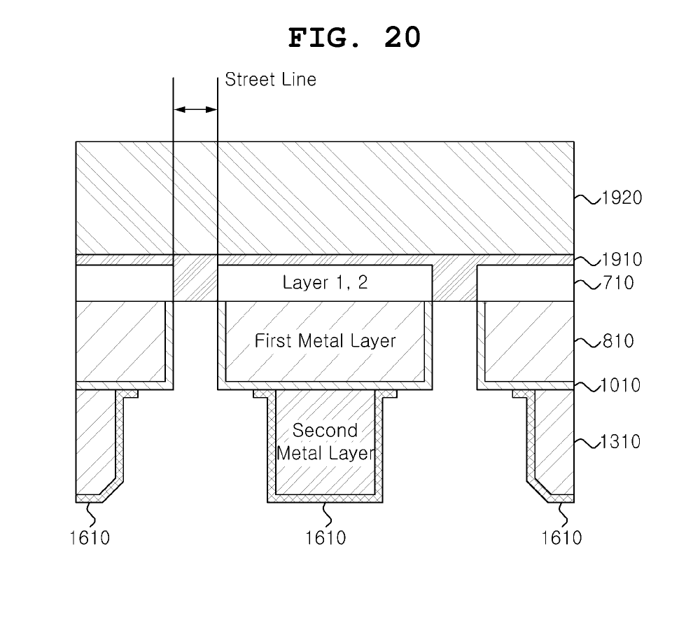

Returning back to FIG. 3, as sown in FIG. 20, a fabrication method of semiconductor device is the street lines of one or more metal layers (710), where the etch barrier is not plated, are separated by wet chemical etching (S370).

FIG. 20 shows a cross sectional view of the wafer where the metal is etched without having protected by etch stop layer according to the processing example of this invention.

FIG. 3 shows the step S350 perms before step S370, however, it can be reversed.

Further, the step S370 can be performed without removing part of the thin film from the multiple thin film layers in layer 1 and layer 2, in order to avoid side wall and surface damages of the layer 1 and 2 in the step S350.

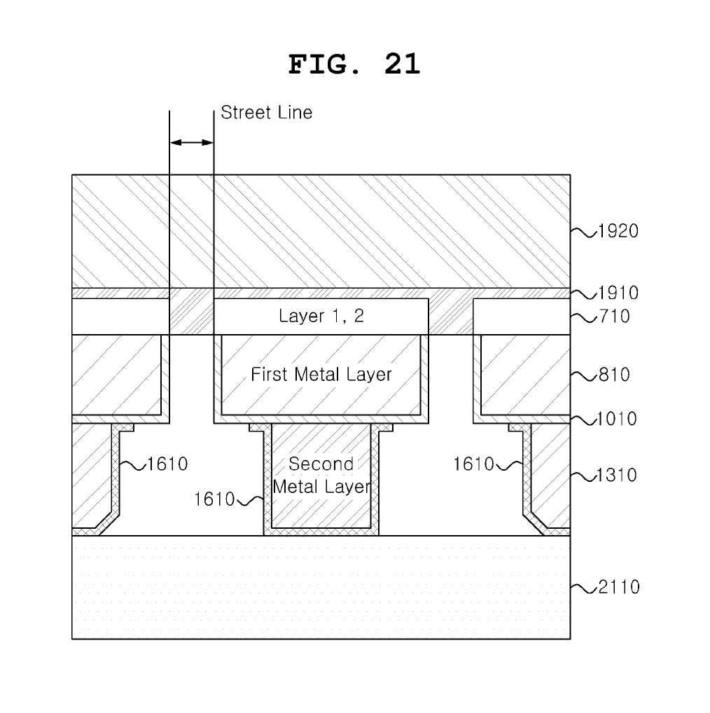

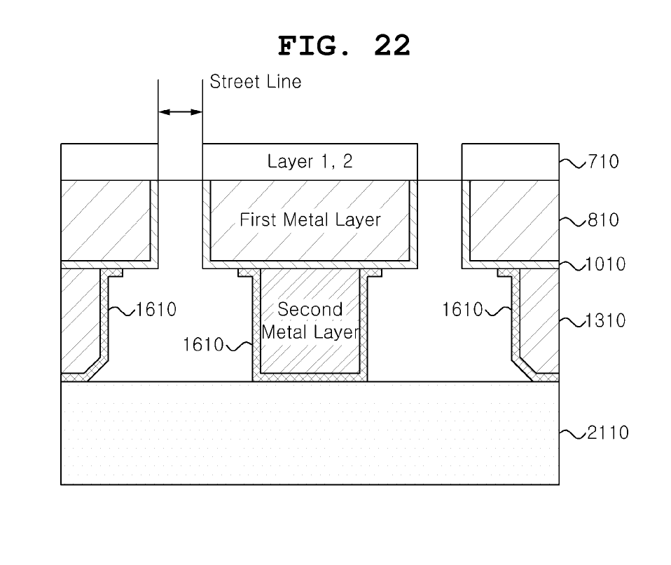

After that, as shown in FIG. 21, a fabrication method of semiconductor device is to attach expanding tape (2110) (S380), and removing the support layer as shown in FIG. 22. A method to remove the support layer (S390) is to expose UV light to the UV tape (1920) and removing UV tape and positive PR (1910).

FIG. 21 shows a cross sectional view of the wafer where the expanding tape is attached on the second metal layer according to the processing example of this invention.

FIG. 22 shows a cross sectional view of the wafer where the support layer is removed according to the processing example of this invention.

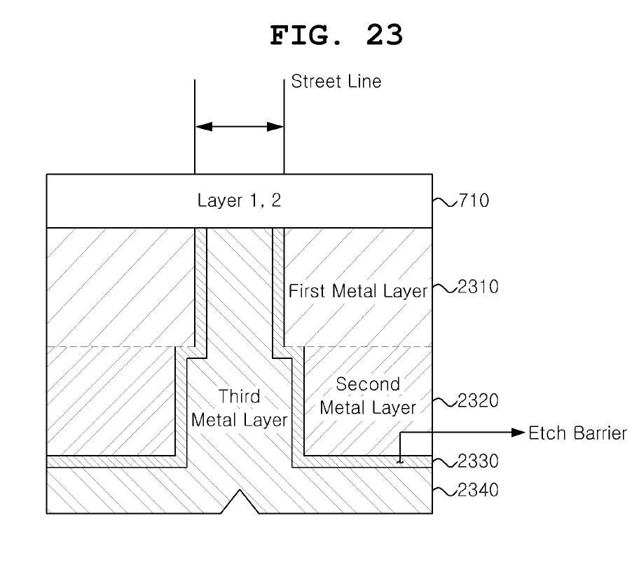

FIG. 23 shows a cross sectional view of the wafer where the etch stop layer and multiple metal layers are plated according to another processing example of this invention.

As shown in FIG. 23, the first metal layer (2310) is plated on the semiconductor device layer and the layer 1 and layer 2 (710) along the first pattern. The first pattern is representing the street line.

Next, the first metal layer (2310) and the second metal layer (2320) are plated along the second pattern. The first metal layer (2310) and the second metal layer (2320) can be chosen from Cu or Cu alloy, and the physical properties of the first metal layer (2310) and the second metal layer (2320) are described previously.

The second pattern is similar to the first pattern, however, the second pattern area is smaller than the first pattern, which are described earlier.

Next, etch barrier layer (2330) is plated on the first metal layer (2310) and the second metal layer (2320). Consecutively, the third metal layer (2340) is plated on the etch barrier layer (2330). In particular, empty space created by etch barrier (2330) that is representing the street line will be filled with the third metal layer (2340).

As the empty space filled with the third metal layer (2340), the first metal layer (2310) and the second metal layer (2320) are physically connected, hence providing a mechanical support and forming a single wafer.

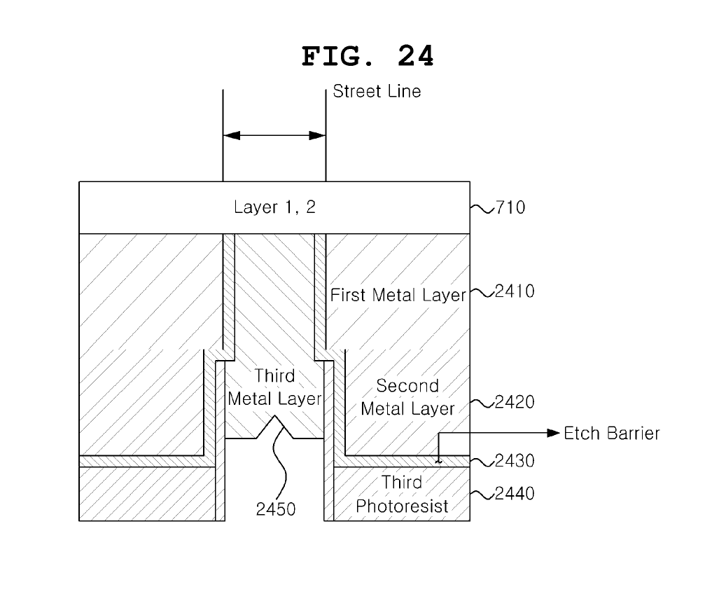

FIG. 24 shows a cross sectional view of the wafer where the etch stop layer and multiple metal layers are plated according to another processing example of this invention.

As shown in FIG. 24, the first metal layer is plated on the semiconductor device layer and diffusion barrier layer (layer 1 and 2 (710)) along the first pattern, consecutively, the second metal layer (2420) is plated on the first metal layer (2410) along the send pattern. Following processes up to etch barrier (2430) plating are identical to the process example shown in FIG. 23.

Next, before the third metal layer (2450) plating, the third photo-resist (2440) is coated that is representing the third pattern. As the third photo-resist (2440) is coated in advance, the third metal layer (2450) can be effectively filled the empty space in between the etch stop layer (2430) located on the street lines.

The third metal layer that fills the empty space between the etch barrier layer so that connects the individual device in the first metal layer, hence forming the wafer is already explained in FIG. 23.

While the present invention has been described in conjunction with specific details, such as specific configuration elements, and limited examples and diagrams above, these are provided merely to help an overall understanding of the present invention, the present invention is not limited to these examples, and various modifications and variations can be made from the above description by those having ordinary knowledge in the art to which the present invention pertains.

Accordingly, the technical spirit of the present invention should not be determined based on only the described examples, and the following claims, all equivalent to the claims and equivalent modifications should be construed as falling within the scope of the spirit of the present invention.

What is claimed is:

1. A method for manufacturing a semiconductor device, the method comprising:
forming a light emitting semiconductor device layer that emits light by current injection; and
forming at least one metal layer with etch barrier plated thereon on the semiconductor device layer, wherein the at least one metal layer provides mechanical support to the semiconductor device, wherein the etch barrier is plated on the at least one metal layer in a direction that the etch barrier can prevent side wall under-cut when the street lines are separated by wet chemical etching.

2. The method of claim 1, forming the at least one metal layer further comprises:
filling the street lines by additional plating after the etch barrier is plated on the at least one metal layer.

3. The method of claim 1, forming the at least one metal layer further comprises:
forming at least one other metal layer, between the semiconductor device layer and the at least one metal layer or between two layers of the at least one metal layer, having a thermal expansion coefficient that the at least one other metal layer can relief stress or prevent crack generation caused by thermal shock due to thermal coefficient mismatch between the at least one metal layer and the semiconductor layer.

4. The method of claim 1, forming at least one metal layer comprises:
forming a first metal layer on the semiconductor device layer using a first pattern;
forming a second metal layer on the first metal layer using a second pattern.

5. The method of claim 4, forming the first metal layer comprises:
forming the first metal layer having thickness at least 40 mm if the first metal layer and the second metal layer is plated with pure Cu or other metals having stress level within +/−10% of pure Cu and if total plating thickness is at least 80 mm.

6. The method of claim 4, forming the first metal layer comprises:
forming a first photo-resist on the street lines of the semiconductor device layer;
plating the first metal layer using the first pattern on the area where the first photo-resist is not formed;
removing the first photo-resist; and
plating a first etch barrier on the first metal layer, including on sidewalls of the first metal layer.

7. The method of claim 6, wherein the first metal layer is composed of Cu or Cu alloy having the plating stress in the range of −0.2 kgf/mm²˜+1.0 kgf/mm².

8. The method of claim 4, forming the second metal layer comprises:
forming a second photo-resist on inverse area of the second pattern;
plating the second metal layer using the second pattern on the area where the second photo-resist is not formed;
removing the second photo-resist;
forming a third photo-resist on a part of the second metal layer that is positioned on the street lines;
plating a second etch barrier on the second metal layer where the third photo-resist is not formed; and
removing third photo-resist.

9. The method of claim 4, forming the second metal layer comprises:
plating a first plated layer including Cu or Cu alloy, having a thickness in the range of 55%˜65% of total plating thickness including thicknesses of the first metal layer and the second metal layer, with a first material same as the first metal layer, if the first metal layer having plating stress in the range of −0.2 kgf/mm²˜+1.0 kgf/mm²; and
plating a second plated layer having 35%˜45% of the total plating thickness with a second material having plating stress in the range of −1.0 kg/fmm²˜+1.0 kgf/mm².

10. The method of claim 1, further comprises:
removing the street lines of the semiconductor device layer using physical cutting or chemical etching, in order to form individually separated semiconductor devices; and
removing a part of the at least one metal layer lying on the street lines, the part of the at least one metal layer is not covered with the plated etch barrier using wet etching.

11. The method of claim 10, wherein removing the street lines of the semiconductor device layer is performed before removing the part of the at least one metal layer.

12. The method of claim 10, further comprises:
forming a binding layer which binds a plurality of the individually separated semiconductor devices within a wafer, after the street lines of the semiconductor device layer is removed and before the part of the at least one metal layer is removed.

13. The method of claim 12, forming the binding layer comprises:
coating a protective photo-resist including positive photo-resist on the surface of the semiconductor device layer; and
attaching UV tape on the positive photo-resist.

14. The method of claim 13, coating the protective photo-resist fills gap among the individually separated semiconductor devices, wherein the protective photo-resist having a thickness at least 3 micrometer.

15. The method of claim 13, further comprises;
attaching an expanding tape to at least one metal layer having higher adhesion force than the adhesion force between the positive photo-resist and the UV tape, after removing the part of the at least one metal layer;
transferring the individually separated semiconductor devices from binding layer to the expanding tape; and
removing the binding layer and cleaning.
